(19) United States
(12) Patent Application Publication
(10) Pub. No.: US 2010/0154860 A1
(43) Pub. Date: Jun. 24, 2010

(54) Collapsible stand for rollable solar panel

(76) Inventor: Tom Ferghana Rogers Fereday, Sydney (AU)

Correspondence Address: JAMES C. EAVES JR.;GREENEBAUM DOLL & MCDONALD PLLC, 3500 NATIONAL CITY TOWER, 101 SOUTH FIFTH STREET, LOUISVILLE, KY, 40202, US

(21) Appl. No.: 12/592,721

(22) Filed: Dec. 1, 2009

(30) Foreign Application Priority Data
Dec. 1, 2008 (AU) 2008906200

(51) Int. Cl. H01L 31/045; F16M 11/04; F16M 11/24; F16M 11/14

(52) U.S. Cl. 136/245; 248/125.8; 248/122.1; 248/124.2

(57) ABSTRACT

The invention provides a collapsible stand assembly for an accessory, the stand assembly including a base, a mounting head, and at least one support member, the at least one support member being adapted in a collapsed configuration to be stored with the base and the mounting head, the stand being adapted for assembly in an operative configuration wherein the at least one support member releasably connects the accessory to the mounting head and wherein the mounting head is connected to the base.

In one preferred embodiment, the accessory is a rollable solar panel and the at least one support member preferably comprises a plurality of support rods. Preferably also, the solar panel is generally rectangular in shape and is adapted to be rolled, when not in use, into a hollow cylinder defining an internal generally cylindrical void region.

This application claims the benefit of Australian Patent Application Serial No. 2008906200 filed Dec. 1, 2008, for Collapsible Stand for Rollable Solar Panel.

### FIELD OF THE INVENTION

The present invention relates generally to a portable accessory stand assembly. The invention has been developed specifically for use in connection with solar panels, and more particularly with rollable solar panels and will be described primarily with reference to this technical application. It should be appreciated, however, that the invention is not limited to this particular field of use.

### BACKGROUND OF THE INVENTION

The following discussion of the prior art is intended to present the invention in an appropriate technical context and allow its advantages to be properly appreciated. Unless clearly indicated to the contrary, however, reference to any prior art in this specification should not be construed as an express or implied admission that such art is widely known or forms part of common general knowledge in the field.

Developments in technology continue to push the limits of outdoor habitation, adventure and survival. Equipment for use in connection with hiking, camping, canyoning, kayaking, yachting, adventuring, mountaineering and the like continues to be adapted and refined through the use of stronger or lighter materials, better insulation, more efficient designs and other technological innovations. However, many new technologies such as lights, mobile phones, satellite phones, personal music players, laptop computers, GPS navigational aids, radio transceivers, portable radios and DVD players, televisions, food coolers, heaters and the like require some form of electric power. Access to such power remains a significant challenge in remote locations.

Various battery technologies are, of course, well known as portable sources of electric power. However, the cumulative weight of batteries in multiple devices can be significant and limitations in battery life is a perennial issue. Spare batteries add further weight and rechargeable batteries require an external source of power for charging. In some circumstances, this factor can be life-threatening, for example if emergency assistance is required in remote locations and radio, mobile phone or GPS navigation batteries run flat, with no means of recharging.

Solar panels offer a potential solution to these difficulties, by providing a renewable source of electric power, dependent only upon the availability of sunlight. However, given the surface area typically required, rigid solar panels of known design are impractical in the present context, due to their relative size, weight, shape and fragility.

In an attempt to address some of these problems, thin-film rollable solar panels have also been developed. While relatively more portable, however, such panels inherently present new challenges and problems, including particularly the difficulty of adequately supporting and orienting the panels when unrolled, for efficient and effective operation. In this regard, it would be appreciated by those skilled in the art that unless these panels can be maintained in a substantially flat orientation, and aligned as directly as possible toward the sun, their operational efficiency will be significantly compromised. Moreover, although rollable solar panels are substantially more robust than conventional rigid panels of comparable size, they are nevertheless susceptible to cell damage if mis-handled or deformed beyond their intended design limits, for example by being rolled too tightly or inadvertent folded or creased.

These issues, which relate to the storage and transportation as well as the use of rollable solar panels, have hitherto prevented the widespread adoption of such panels in the context of camping, hiking, mountaineering and outdoor adventuring, as well as in other potential applications.

It is an object of the present invention to overcome or ameliorate one or more of the deficiencies of the prior art, or at least to provide a useful alternative.

### SUMMARY OF THE INVENTION

Accordingly, the invention provides a collapsible stand assembly for an accessory, the stand assembly including a base, a mounting head, and at least one support member,
the at least one support member being adapted in a collapsed configuration to be stored with the base and the mounting head,
the stand being adapted for assembly in an operative configuration wherein the at least one support member releasably connects the accessory to the mounting head and wherein the mounting head is connected to the base.

In one preferred embodiment, the accessory is a rollable solar panel and the at least one support member preferably comprises a plurality of support rods. Preferably also, the solar panel is generally rectangular in shape and is adapted to be rolled, when not in use, into a hollow cylinder defining an internal generally cylindrical void region.

The assembly preferably further includes retaining means adapted to retain the solar panel in the rolled configuration. In one embodiment, the retaining means includes a selectively releasable “Velcro” strap.

In the operative configuration, the support rods preferably connect the solar panel to the mounting head, and support the panel in an unrolled, substantially flat configuration, for use.

Preferably, the base and the mounting head define respective generally circular peripheral edge flanges adapted for alignment or engagement with corresponding ends of the cylinder defined by the solar panel in the rolled configuration. In this way, the base and the mounting head preferably close off the corresponding ends of the cylindrical void region defined by the rolled solar panel. In one embodiment, in the collapsed configuration, the respective flanges of the base and the mounting head form a spool, around which, in use, the solar panel is rolled and secured. Preferably, the support rods are captively retained within the void region, between the base and the mounting head, with the assembly in the collapsed configuration.

In one embodiment, the assembly further includes a generally tubular container, adapted to retain the rolled solar panel between the mounting head and the base, and thereby to retain the support rods within the void region, in the collapsed configuration. In one embodiment, the container includes a generally tubular bag, formed from a relatively soft textile material. The tubular bag preferably includes an open top, incorporating a peripheral fastening cord. This may take the form of a manually adjustable draw-string, or a resilient elastic or rubber band, for example.

The mounting head preferably incorporates a circumferential locating groove adapted for secure engagement by the fastening cord of the bag, such that the bag itself holds the stand assembly and the solar panel together in the collapsed configuration, with only an upper portion of the mounting head above the groove protruding from the bag. Preferably, the bag is waterproof and includes at least one pocket adapted to contain an electronic device such as a mobile phone. In other embodiments, the container may take the form of substantially rigid tube or other suitable shape, formed from plastics or other suitable materials.

In yet other embodiments, the mounting head may be adapted for direct connection to the base in the collapsed configuration, for example by means of the support rods or by other means, so as to obviate the need for the container to keep the components of the assembly together in the collapsed configuration.

Preferably, the support rods are formed from a relatively lightweight, resilient, flexible but strong material, such as fibreglass or carbon fibre. Each support rod is preferably adapted for insertion into a corresponding rod socket formed in the mounting head such that in the assembled configuration, the rod sockets locate and orient the rods at predetermined angles with respect to the mounting head.

The remote end of each support rod preferably terminates in a respective hook formation. The hook formations are preferably adapted for engagement with complementary eyelets disposed at or adjacent respective corners of the solar panel. The rods are preferably sized and oriented such that in the operative configuration, engagement of the hooks with the corresponding eyelets requires a predetermined degree of resilient bending of the support rods, which in turn induces a corresponding degree of biaxial tension in the solar panel, thereby positively retaining the panel in a substantially flat orientation for optimal operational efficiency.

In one embodiment, the mounting head incorporates an end cap including a top housing, the top housing preferably containing a plurality of tension reels, each independently supporting a corresponding retractable tether cord. In one preferred embodiment, there are four such tether cords, each tether cord extending through the internal bore a corresponding support rod, and each preferably terminating in a loop formation adapted to be secured to the ground with a tent peg or similar fastener. In this way, when required, one or more of the tether cords can be selectively deployed to provide additional stability to the panel, but when not required, the tether cords are automatically retracted into the mounting head by their respective tension reels. Advantageously, the tether loops are oversized with respect to the rod bores, which prevents the tether loops from being fully retracted through the bores. This makes the tethers readily accessible when required for use, and also prevents the rods from becoming inadvertently separated from the mounting head.

In one embodiment, at least one of the support rods is selectively extensible. The rod extensibility in different embodiments may be achieved by various means including by telescopic extension, by joining two or more sub-rods together, by unfolding and locking hinged rods, or by other suitable means.

In one preferred embodiment, the assembly includes four support rods, adapted respectively to support the four corners of a generally rectangular solar panel. Each of the four rods is preferably extensible by at least a factor of two.

Preferably, the mounting head is adapted for connection to the base in the operative configuration by a base connection mechanism, which permits selective adjustment of the orientation of the mounting head, and hence the solar panel or other accessory, with respect to the base. This advantageously allows an operator to optimise the alignment of the solar panel, within a predetermined range of adjustability, with respect to the prevailing position of the sun.

In one preferred embodiment, the base connection mechanism includes a spherical joint, comprising a ball formation on the base and a complementary socket formation on the mounting head, or vice versa. Preferably, the socket is formed from a resilient material, such as silicone or rubber, to enable the base to be releasably connected to the mounting head by means of an over-centring press fit.

Preferably, the base includes one or more fittings to improve stability. Optional stability fittings include a plurality of spaced-apart holes by which the base can be anchored to the ground by tent pegs, a threaded socket or other standardised fitting by which the base can be mounted to a tripod, and/or a channel formation by which the base can be releasably mounted to an external support strut of a tent or similar structure.

The assembly preferably also includes an electrical cord having one end adapted for electrical connection to the solar panel and another end adapted for electrical connection, via suitable fittings or adapters, to a device to be powered by the solar panel. In one preferred embodiment, the adapter includes a female socket of the automotive cigarette lighter type, being thereby compatible with battery chargers for a wide range of electronic devices.

Advantageously, the assembly is adaptable for use with a wide variety of rollable solar panel designs.

### BRIEF DESCRIPTION OF THE DRAWINGS

Preferred embodiments of the invention will now be described, by way of example only, with reference to the accompanying drawings in which:

FIG. 1A shows an assembly, adapted for use with a rollable solar panel, in the fully collapsed configuration according to one embodiment of the invention;

FIG. 1B shows the assembly of FIG. 1A, with the outer container or bag removed;

FIG. 1C shows the assembly in the collapsed configuration, with the rollable solar panel also removed to reveal the other components;

FIG. 2 is an enlarged view showing the removal of the bag, as a transition between FIGS. 1A and 1B;

FIG. 3 shows the assembly in the operative configuration, with the mounting head attached to the base and the support rods extending from the mounting head to support the solar panel;

FIG. 4 shows the assembly of FIG. 3 with the base mounted on the ground and the solar panel adjustably oriented toward the sun (with a second assembly, fully collapsed and stored in its bag, in the foreground);

FIG. 5 shows the assembly of FIG. 3, with the base mounted to a tripod;

FIG. 6A shows the assembly of FIG. 3, with the base mounted to the framing strut of a dome-style tent;

FIG. 6B is an enlarged view from FIG. 6A, showing the base mounted to the tent framing strut;

FIG. 7A is a perspective similar to FIG. 1C, showing the primary components of the assembly, in the collapsed configuration, with the rollable solar panel and bag removed;

FIG. 7B is a side elevation of the assembly shown in FIG. 7A, with the rollable solar panel included in the collapsed configuration;

FIG. 7C is a front elevation of the assembly shown in FIG. 7A;

FIG. 7D is a cross-sectional view of the assembly shown in FIG. 7C;

FIG. 7E is a cross-sectional view of the assembly shown in FIG. 7B;

FIG. 8 is an exploded perspective view showing the mounting head of the assembly, including the top and bottom housings;

FIG. 9 is a transverse cross-sectional view of the mounting head shown in FIG. 8;

FIG. 10 is an exploded perspective view of the base of the assembly;

FIG. 11 shows a series of support rods, each of different length and adapted for use with a solar panel of different size, each support rod being shown in the non-extended configuration, with a respective tether cord extending therethrough;

FIG. 12 is an enlarged perspective view showing the rod end fitting adapted for connection to the remote end of each support rod;

FIG. 13 is a perspective view showing the end of one of the support rods, with the associated rod end fitting attached, and the tether cord partially manually extended by means of the associated loop fitting; and

FIG. 14 shows a series of rollable thin-film solar panels of different length, of the type suitable for use in connection with the invention.

### PREFERRED EMBODIMENTS OF THE INVENTION

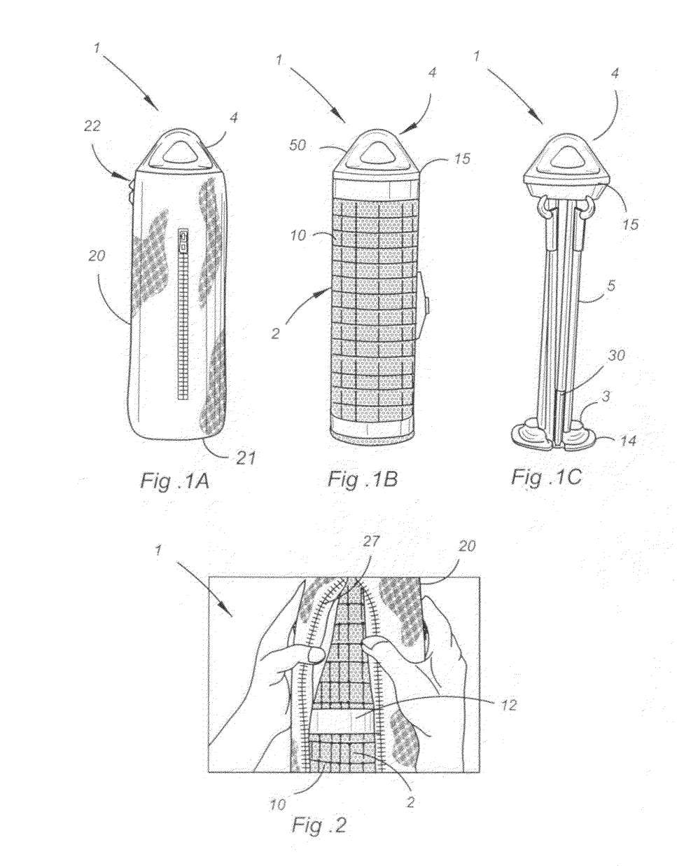

Referring initially to FIGS. 1 to 3, the invention provides a collapsible stand assembly 1 for an accessory. In this preferred embodiment, the accessory takes the form of a thin-film amorphous silicon rollable solar panel 2. The stand assembly 1 includes a base 3, a mounting head 4, and a plurality of support rods 5. As best seen in FIG. 1C, the support rods are adapted to be stored between the base 3 and the mounting head 4 in the collapsed configuration. In the operative configuration, the support rods 5 releasably connect the rollable solar panel or other accessory to the mounting head, with the mounting head connected to the base, as described in more detail below.

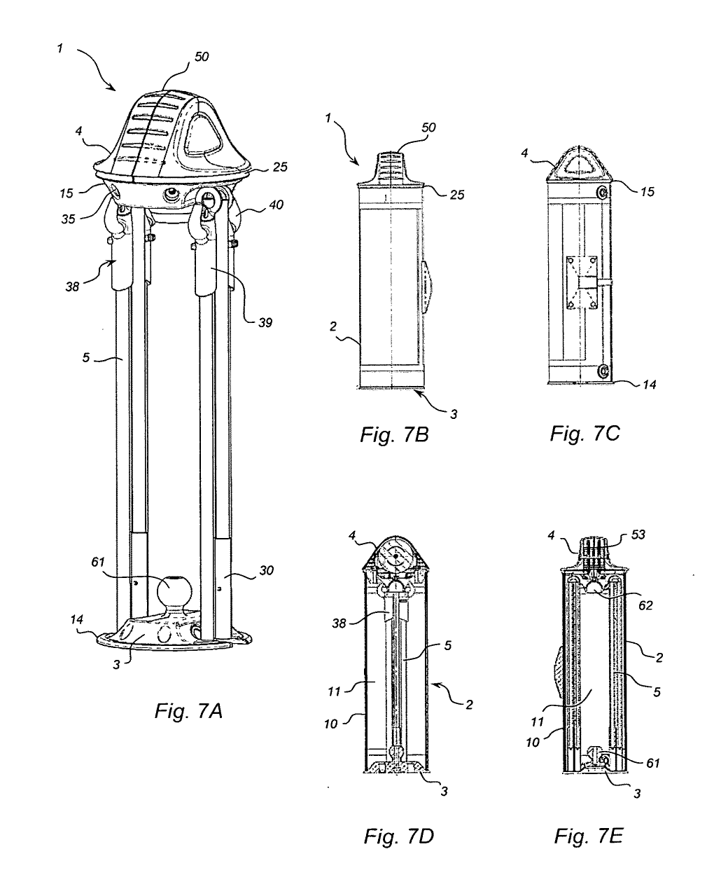

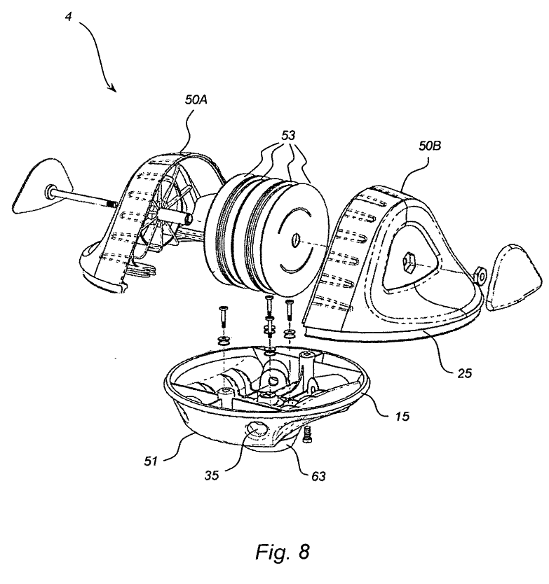

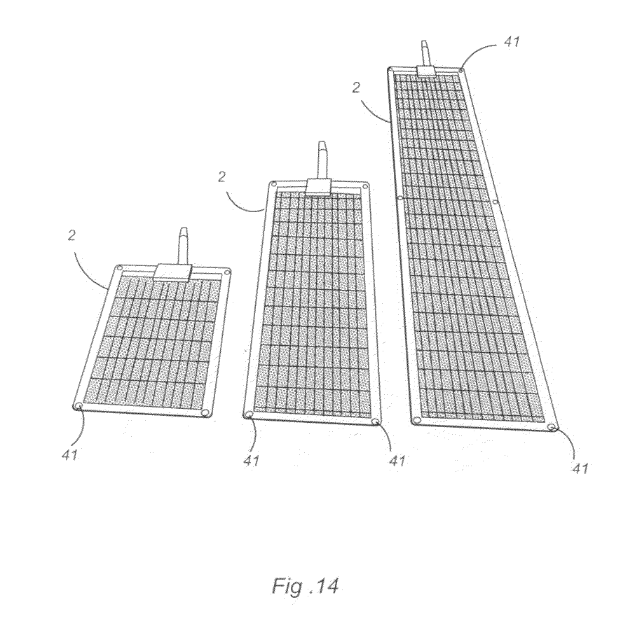

The solar panel is generally rectangular in shape when fully extended, but is adapted to be rolled, when not in use, into a hollow cylinder 10 defining an internal generally cylindrical void region 11, as best seen in FIGS. 7D and 7E. The assembly can be adapted for use with solar panels of virtually any size or shape. However, suitable panels currently available are around 300 mm wide and between 500 mm and around 2,000 mm in length, the preferred size depending upon power requirements and space constraints, for particular applications. Typical examples are shown in FIG. 14. The assembly further includes retaining means adapted to retain the solar panel in the rolled configuration when not required for use. In this embodiment, as best seen in FIG. 2, the retaining means takes the form of a simple “Velcro” strap 12.

As best seen in FIGS. 1B, 1C and 7A to 7E, the base 3 and the mounting head 4 define respective generally circular peripheral edge flanges 14 and 15, adapted for alignment or engagement with corresponding ends of the cylinder 10 defined by the solar panel in the rolled configuration. In this way, as best seen in FIG. 1B, the base and the mounting head effectively close off the corresponding ends of the internal cylindrical void region 11 defined by the rolled solar panel. As will be apparent from FIGS. 7A to 7E, the support rods 5 are captively retained within this void region, when the assembly is collapsed. In some embodiments, in the collapsed configuration, the respective edge flanges 14 and 15 of the base and the mounting head effectively form a spool around which, in use, the solar panel is rolled and secured.

As best seen in FIG. 1A, the assembly further includes a generally tubular container which is adapted to retain the rolled solar panel 20, the mounting head and the base, in close-fitting relationship, and thereby to retain the support rods within the void region 11, in the collapsed configuration. More specifically, in this embodiment, the container takes the form of a generally tubular bag formed from a relatively soft, substantially waterproof, synthetic textile material.

The bag 20 includes a closed bottom 21 and an open top 22, incorporating a peripheral fastening cord contained substantially within a seam formed in an upper marginal edge of the bag around the open top. The fastening cord preferably takes the form of a manually adjustable draw-string, or a resilient elastic or rubber band (not shown). As best seen in FIG. 7A, the mounting head 4 incorporates a circumferential locating groove 25, adapted for secure engagement by the fastening cord of the bag, such that the bag itself holds the stand assembly and the solar panel together in the collapsed configuration, with only an upper portion of the mounting head, above the groove 25, protruding from the bag. The bag includes one or more pockets 26, which preferably incorporate respective watertight zip fasteners or other suitable closures, to contain electronic devices such as mobile phones, connecting cables, electrical adaptors and related ancillary equipment (not shown).

As best seen in FIG. 4, a zip fastener 27 extends longitudinally around the bag (see also FIG. 2), enabling it to open out into two halves, and thereby to remain together with the other components with the stand assembly and the solar panel when operationally deployed. Conveniently, in this way, the device to be charged can remain in the storage pocket of the bag, to minimise the risk of misplacement or damage. This includes the avoidance of water damage, if the pocket is suitably sealed.

It should be appreciated that in other embodiments (not shown), the container may take the form of a substantially rigid tube, or a body or vessel of other suitable shape, formed from plastics, metal alloys, composites such as carbon fibre, or other suitable materials.

In a further alternative embodiment (also not shown), the mounting head is adapted to be connected to the base in the collapsed configuration by means of the support rods themselves, or by an alternative connection mechanism, so as to obviate the need for the container to keep the components of the stand assembly and the solar panel or other accessory, securely together.

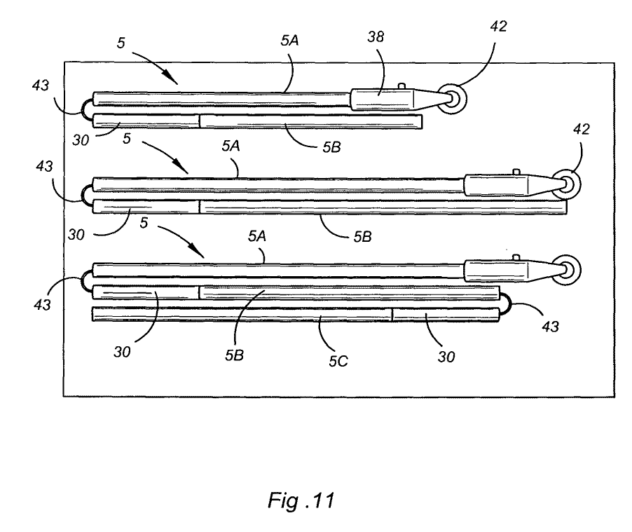

The support rods themselves are preferably formed as hollow tubes from a relatively lightweight, resilient, flexible but strong material, such as fibreglass or carbon fibre. As best seen in FIG. 11, the support rods are selectively extensible. A number of extension mechanisms are envisaged for these rods, including telescopic extension mechanisms, hinge mechanisms, and the like. In the embodiment shown, however, as best seen in FIG. 11, each rod 5 is comprised of two or more smaller sub-rods 5A, 5B 5C etc. adapted to be releasably connected and retained in coaxial alignment by means of respective sleeves 30. This mechanism enables each rod to be doubled, tripled or even quadrupled in length from the collapsed to the extended configuration, depending upon how many sub-rods are incorporated into each rod assembly.

The proximal end of each support rod 5 is adapted for insertion into a corresponding support rod socket 35, formed in the mounting head, such that in the assembled configuration, the rod sockets locate and orient the associated support rods at predetermined angles with respect to the mounting head. This embodiment includes four rods and four corresponding rod sockets in the mounting head. It should be appreciated, however, that different numbers of rods and sockets may be provided, depending upon the intended application. In particular, more sockets than rods may optionally be provided, to allow greater flexibility in terms of rod positioning and orientation with respect to the mounting head.

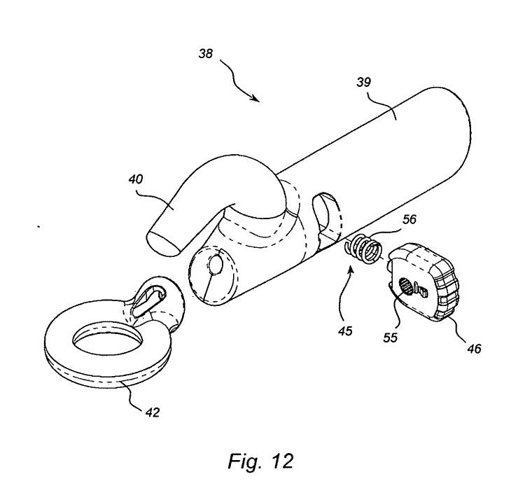

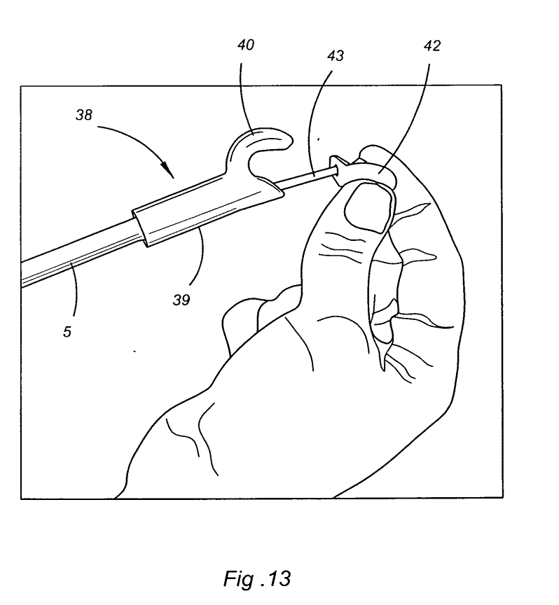

The remote end of each support rod terminates in a rod-end fitting 38, as best seen in FIGS. 12 and 13. Each rod-end fitting 38 includes a sleeve formation 39 adapted to be secured over the remote end of the associated support rod 5, a hook formation 40 adapted for engagement with a corresponding eyelet 41 formed in a corresponding corner of the solar panel (see FIG. 14), and a loop formation 42 adapted for connection to a tether cord 43, as described in more detail below. A spring-loaded tether retraction control mechanism 45 incorporating a spring-loaded locking release button 46 is provided for controlling the tether cord, as seen in FIG. 12 and as described in more detail below.

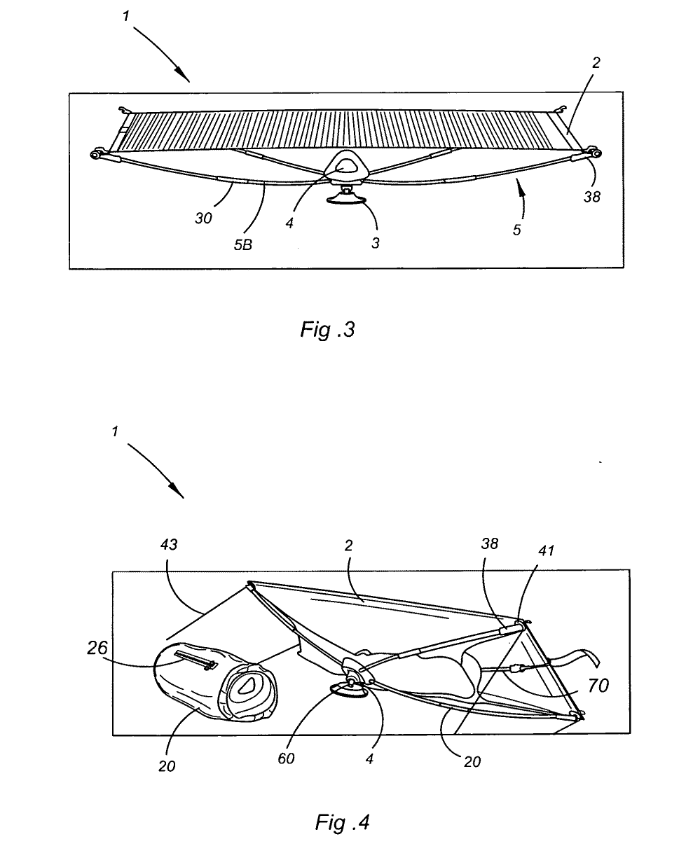

The support rods are sized and oriented such that in the operative configuration, engagement of the hooks 40 with the eyelets 41 in the respective corners of the solar panel requires a predetermined degree of resilient bending of the support rods. This in turn induces a corresponding degree of biaxial tension in the solar panel, which ensures that the panel is positively retained in a flat orientation, as best seen in FIGS. 3 to 5. This feature is significant because without some positive straightening or stretching forces being applied as a result of the induced bending tension in the support rods upon assembly, the solar panel may tend to “curl up” or otherwise deform, particularly if the panel has been retained in the rolled configuration for some time. This curling tendency or other deviations, from the intended flat orientation, can otherwise result in sub-optimal alignment of at least some of the cells within the panel with respect to the sun, which in turn can significantly compromise the efficiency and power output of the panel. In this regard, test results indicate that by ensuring accurate co-planar alignment of the cells within the panel, in combination with optimal alignment of the panel as a whole toward the sun, power output can be increased by up to 35% relative to the output of the same panel when non-optimally aligned.

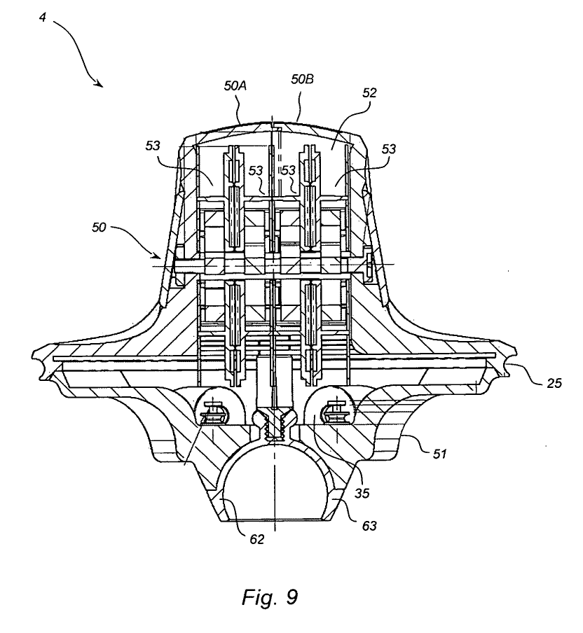

As best seen in FIGS. 8 and 9, the mounting head incorporates an end cap or top housing 50 formed in two halves 50A and 50B, and a bottom housing 51. The top and bottom housings together form an internal compartment 52 within the mounting head, adapted to accommodate a series of four tension reels 53. Each of these tension reels independently supports a corresponding retractable tether cord 43. Each tether cord extends through the internal bore of a corresponding support rod. The remote end of each tether cord terminates in a corresponding loop formation 42, as shown in FIGS. 11, 12 and 13. Each loop formation 42 is adapted to be secured to the ground with a tent peg or otherwise fastened to a stabilising object, surface, or base. In this way, when required, one or more of the tether cords 43 can be selectively deployed to provide additional stability to the panel and stand assembly as may be required, for example, in high wind conditions. However, when not required, the tether cords may be automatically retracted into the mounting head by their respective tension reels, regulated by means of the retraction control mechanisms 45 incorporated into the respective rod-end fittings 38.

Turning now to describe the tethering mechanism in more detail, as best seen in FIG. 12, each retraction control mechanism 45 includes a tether release button 46, a tether control aperture 55 through which the respective tether passes, and a locking spring 56 to bias the release button outwardly toward a tether-locking position. Thus, in the normal position, with the tether release button 46 not depressed, the spring 56 biases the button outwardly into a configuration in which the tether, passing through the control aperture 55, is locked in its current position. When the tether release button is manually depressed, however, the biasing force of the locking spring is overcome, and the control aperture 55 is moved toward coaxial alignment with the internal bore of the sleeve of the rod end fitting. This allows the tether cord to pass freely through the control aperture, which in turn allows the tether cord either to be extended further or else to be automatically retracted by the associated tension reel.

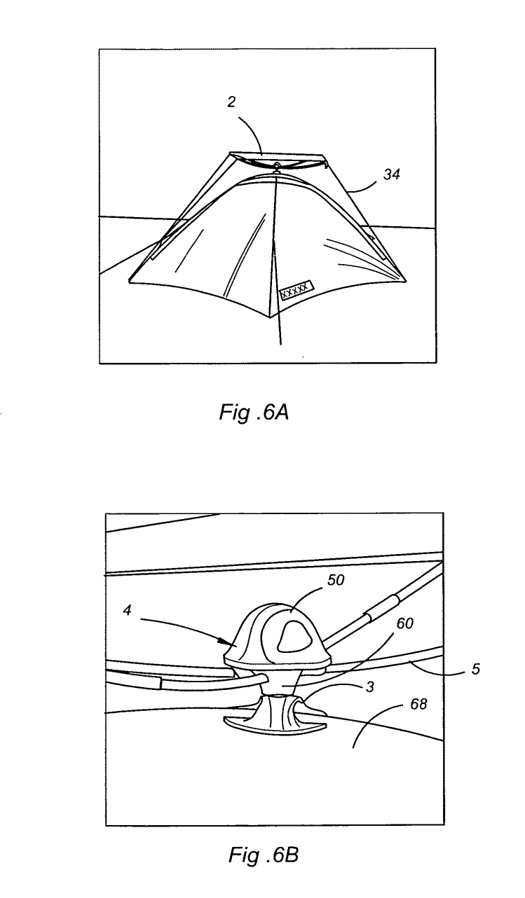

As will be appreciated from FIGS. 12 and 13, the tether loops 42 are oversized with respect to the rod bores, which prevents the tether loops from being fully retracted through the bores. This arrangement makes the tethers readily accessible when required for use, by means of their respective loop formations. It also prevents the rods themselves from becoming inadvertently separated from the mounting head. The tethers can be seen operatively deployed in FIGS. 4 and 6A. It should be appreciated, however, that in alternative embodiments, a smaller or larger number of tether cords may be used, and these cords need not necessarily be mounted on independent tension reels. In some embodiments, no internal tether cords are provided.

The assembly further includes a base connection mechanism 60 adapted to permit the mounting head to be releasably connected to the base in the operative configuration. Preferably, this connection mechanism permits selective adjustment of the orientation of the mounting head, and hence the solar panel or other accessory, with respect to the base. This advantageously allows the operator to optimise the alignment of the solar panel, within a predetermined range of adjustability, with respect to the prevailing position of the sun, as illustrated for example in FIG. 4.

More specifically, the base connection mechanism in this embodiment includes a spherical joint, comprising a ball formation 61 depending upwardly from the base 3 and a complementary socket formation 62 formed in the underside of the bottom housing 51 of the mounting head 4. As best seen in FIG. 9, the socket formation 62 is defined by an insert 63 formed from a resilient material such as silicone or rubber. One particularly suitable material for this purpose is injection-moulded liquid silicone rubber (LSR), which has been found to provide excellent thermal stability over a wide operating temperature range, good flexibility and a relatively non-stick surface. The inherent resilience the also enables the ball formation to be releasably connected to the socket formation by means of a simple over-centering press fit. The ball and socket are, however, designed for an interference fit, once engaged, so as to allow selective adjustment of the orientation of the mounting head with respect to the base by the operator, but to provide sufficient residual frictional interference to retain the mounting head in the adjusted orientation.

In alternative embodiments (not shown) the base connection mechanism may incorporate a powered drive mechanism, for example using internal servo-motors, to facilitate remote control of the orientation of the mounting head and hence the solar panel with respect to the base. Mechanical drive mechanisms, such as manually windable clockwork mechanisms are also envisaged, to minimise the use of electrical power. In a further variation, a mechanical or computerised control system may also be provided, for example to allow the solar panel to be programmed to track the movement of the sun throughout the day, thereby ensuring optimal efficiency and power output from the panel, even if the assembly is left unattended.

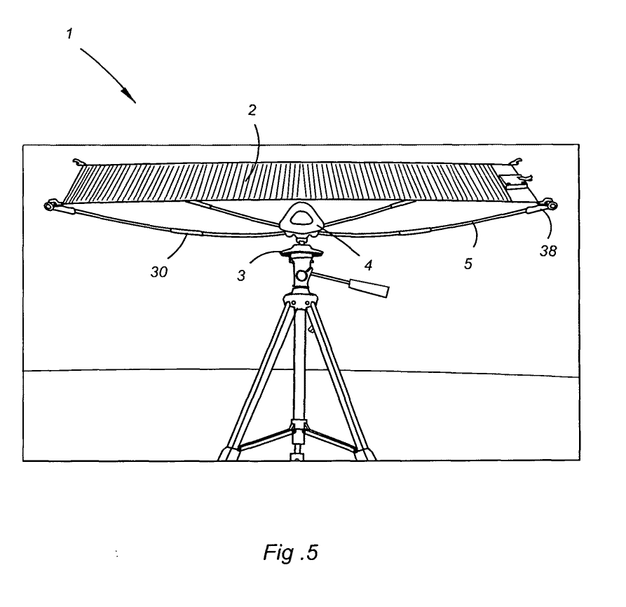

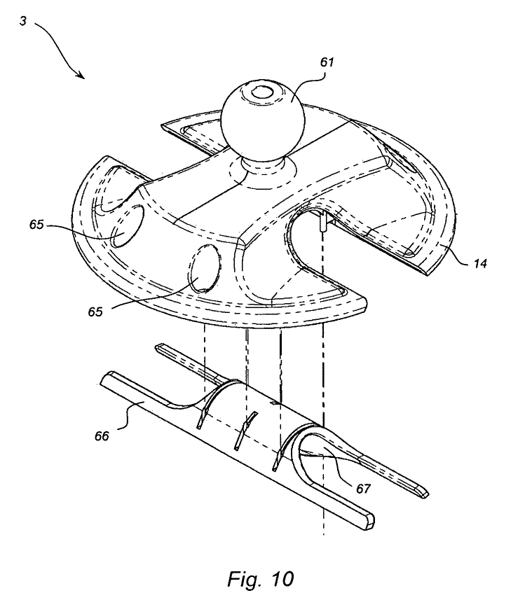

As best seen in FIG. 10, the base further includes several different stability fittings to enable the assembly to be anchored or stabilised in a variety of different circumstances. Firstly, the base includes a series of four spaced apart generally vertically oriented apertures 65, to permit the base to be anchored to the ground by tent pegs (see FIG. 4). The underside of the base also incorporates a threaded female socket by which the base can be mounted directly to a tripod or similar support structure (see FIG. 5). The base further incorporates an insert 66, again formed of an elastomeric material such as injection-moulded LSR. This insert defines an internal transverse channel formation 67 by which the base can be releasably mounted to an external framing strut 68 of a dome style tent or similar structure (see FIGS. 6A and 6B). Again, this channel insert is adapted to be connected to the tent framing strut with an over-centering press fit, providing a residual interference fit to ensure operational stability in situ. Different inserts 66 may be provided to accommodate framing struts of different diameters or alternatively, the insert may be designed with sufficient resilience to effectively accommodate framing struts of different diameter. Common framing struts currently in use range between 7.5 mm and 12 mm in diameter and in the preferred embodiment, the resilient insert 66 is designed to deform sufficiently to accommodate any framing strut falling generally within this range.

The assembly further includes a power cord 70, having one end adapted for electrical connection to the solar panel (see FIG. 4). The other end is adapted for electrical connection, via suitable fittings or adaptors, to the device to be powered by the solar panel, such as a mobile phone, laptop computer, GPS navigation unit, “iPod”, lighting, heating or cooling equipment, or the like. One preferred adaptor fitting includes a female socket of the automotive cigarette-lighter type, which is compatible with battery chargers available for a wide variety of consumer electronic devices.

The modular structure of the assembly means solar panels in a variety of sizes and shapes can be readily accommodated, simply by substitution of correspondingly sized sets of support rods. This includes adaptation to other forms of solar panel, including rigid solar panels, and foldable solar panels incorporating segments of the flexible or rigid type. Other accessories or components such as an RF antenna, radio beacon or transmitter, LCD screen, camera or other recording equipment, small satellite or radar dish, telescope, signalling mirror or the like may also be accommodated by substituting support rods and rod-end fittings of appropriate number, size, shape and configuration.

Similarly, alternative configurations of the base and/or the mounting head may be substituted as required for particular mounting applications. For example, one special-purpose base or base fitting is adapted for direct connection to the roof racks or roof bars of a car or similar vehicle. Snow spikes, straps or spikes for fastening the base to tree trunks, and other such variations are also envisaged.

The present invention, at least in its preferred embodiments, provides a highly versatile stand assembly adaptable to a wide variety of accessories and applications, including particularly the storage, transportation and deployment of rollable solar panels in outdoor environments, where factors of weight, space efficiency, durability, weather-resistance and optimal performance are especially important. In particular, the invention allows the advantages of rigid solar panels, in terms of optimal flatness and facility for alignment, together with the benefits of rollable solar panels, in terms of portability, durability, flexibility and space-efficiency, to be brought together in an integral product that is lightweight, weatherproof, easily adjustable, and adaptable to a wide variety of outdoor applications.

In this way, the invention in various preferred embodiments alleviates a number of inherent problems previously associated with amorphous silicon thin-film rollable solar panels, and thereby transforms this relatively unrefined technology into a highly usable commercial product, with significantly expanded application in mainstream leisure and other markets. In these and other respects, the invention represents a practical and commercially significant improvement over the prior art.

Although the invention has been described with reference to specific examples, it will be appreciated by those skilled in the art that the invention may be embodied in many other forms.

What we claim is:

1. A collapsible stand assembly for an accessory, the stand assembly including a base, a mounting head, and at least one support member,
the at least one support member being adapted in a collapsed configuration to be stored with the base and the mounting head,
the stand being adapted for assembly in an operative configuration wherein the at least one support member releasably connects the accessory to the mounting head and wherein the mounting head is connected to the base.

2. A collapsible stand assembly according to claim 1, wherein the at least one support member comprises a plurality of support rods, adapted to be stored between the base and the mounting head in the collapsed configuration.

3. A collapsible stand assembly according to claim 2, wherein the accessory is a rollable solar panel adapted to be rolled, when not in use, into a hollow cylinder defining an internal generally cylindrical void region adapted to contain the support rods in the collapsed configuration.

4. A collapsible stand assembly according to claim 3, wherein the support rods in the operative configuration connect the solar panel to the mounting head and support the panel in an unrolled substantially flat configuration.

5. A collapsible stand assembly according to claim 4, wherein the rollable solar panel is substantially rectangular in shape when in the unrolled substantially flat configuration.

6. A collapsible stand assembly according to claim 1, wherein the mounting head is adapted for connection to the base in the operative configuration by a base connection mechanism, which permits selective adjustment of the orientation of the mounting head with respect to the base.

7. A collapsible stand assembly according to claim 6, wherein the base connection mechanism includes a spherical joint.

8. A collapsible stand assembly according to claim 3, further including a retaining mechanism adapted to retain the solar panel in the rolled configuration.

9. A collapsible stand assembly according to claim 8, wherein the retaining mechanism includes a selectively releasable hook and loop fastener.

10. A collapsible stand assembly according to claim 1, wherein the accessory is a rollable solar panel adapted to be rolled, when not in use, into a generally hollow cylinder, and wherein the base and the mounting head define respective generally circular peripheral edge flanges adapted for alignment or engagement with corresponding ends of the cylinder defined by the solar panel in the rolled configuration.

11. A collapsible stand assembly according to claim 10, wherein the base and the mounting head close off corresponding ends of an internal generally cylindrical void region defined by the solar panel in the rolled configuration.

12. A collapsible stand assembly according to claim 11, wherein, in the collapsed configuration, the respective peripheral edge flanges of the base and the mounting head form a spool, around which the solar panel is adapted to be rolled and secured.

13. A collapsible stand assembly according to claim 11, wherein the support rods are adapted to be captively retained within the void region, between the base and the mounting head, with the assembly in the collapsed configuration.

14. A collapsible stand assembly according to claim 3, further including a generally tubular container, adapted to retain the rolled solar panel between the mounting head and the base, and thereby to retain the support rods within the void region, in the collapsed configuration.

15. A collapsible stand assembly according to claim 14, wherein the container includes a generally tubular bag, formed from a relatively soft textile material.

16. A collapsible stand assembly according to claim 15, wherein the tubular bag includes an open top, incorporating a peripheral fastening cord.

17. A collapsible stand assembly according to claim 16, wherein the mounting head incorporates a circumferential locating groove adapted for secure engagement by the fastening cord of the bag, whereby the bag is adapted to hold the stand assembly and the solar panel together in the collapsed configuration, with only an upper portion of the mounting head above the groove protruding from the bag.

18. A collapsible stand assembly according to claim 15, wherein the bag is waterproof and includes at least one pocket adapted to contain a portable electronic communication and navigation device.

19. A collapsible stand assembly according to claim 14, wherein the container comprises a substantially rigid tube.

20. A collapsible stand assembly according to claim 1, wherein the mounting head is adapted for direct connection to the base in the collapsed configuration.

21. A collapsible stand assembly according to claim 20, wherein the mounting head is adapted for direct connection to the base in the collapsed configuration, by means of the support members.

22. A collapsible stand assembly according to claim 1, wherein the support members are formed as elongate support rods from a relatively lightweight, resilient, flexible material.

23. A collapsible stand assembly according to claim 22, wherein each of said support rods is adapted for insertion into a corresponding rod socket formed in the mounting head such that in the assembled configuration, the rod sockets locate and orient the rods at predetermined angles with respect to the mounting head.

24. A collapsible stand assembly according to claim 22, wherein a remote end of each of said support rods terminates in a respective hook formation.

25. A collapsible stand assembly according to claim 24, wherein the hook formations are adapted for engagement with complementary eyelets disposed at or adjacent respective corners of a rollable solar panel.

26. A collapsible stand assembly according to claim 25, wherein the support rods are sized and oriented such that in the operative configuration, engagement of the hooks with the corresponding eyelets requires a predetermined degree of resilient bending of the support rods, thereby to induce biaxial tension in the solar panel, so as positively to retain the panel in a substantially flat orientation for optimal operational efficiency.

27. A collapsible stand assembly according to claim 1, wherein the mounting head incorporates an end cap including a top housing, the top housing containing a plurality of tension reels, each independently supporting a corresponding retractable tether cord, each tether cord extending through an internal bore of a corresponding one of said support members, and each tether cord terminating in a tether loop formation adapted to be secured to the ground by a fastening element such as a tent peg.

28. A collapsible stand assembly according to claim 27, wherein the tether loop formations are oversized with respect to the internal bores, thereby to prevent the tether loops from being fully retracted through the bores and to prevent the support members from becoming inadvertently separated from the mounting head.

29. A collapsible stand assembly according to claim 1, wherein at least one of the support members is selectively extensible.

30. A collapsible stand assembly according to claim 29, wherein the assembly includes four support members in the form of support rods, adapted respectively to support four corners of a generally rectangular solar panel, each of the four support rods being extensible by at least a factor of two.

31. A collapsible stand assembly according to claim 7, wherein the spherical joint forming part of the base connection mechanism comprises a ball formation on the base and a complementary socket formation on the mounting head, or vice versa, the socket being formed from or lined with a resilient material adapted to enable the base to be releasably connected to the mounting head by means of an over-centring press fit.

32. A collapsible stand assembly according to claim 1, wherein the base includes one or more stability fittings.

33. A collapsible stand assembly according to claim 32, wherein the one or more stability fittings are selected from the group comprising:
spaced-apart holes by which the base can be anchored to ground by tent pegs;
a threaded socket or other standardised fitting by which the base can be mounted to a tripod; and
a channel formation by which the base can be releasably mounted to an external support strut of a tent or similar structure.

34. A collapsible stand assembly according to claim 1, further including an electrical cord having one end adapted for electrical connection to a solar panel and another end adapted for electrical connection, via an adapter, to a device to be powered by the solar panel.

35. A collapsible stand assembly according to claim 34, wherein the adapter includes a female socket of the automotive cigarette lighter type, being thereby compatible with battery chargers for a wide range of electronic devices.
